(19) United States
(12) Patent Application Publication
(10) Pub. No.: US 2011/0241187 A1
(43) Pub. Date: Oct. 6, 2011

(54) LEAD FRAME WITH RECESSED DIE BOND AREA

(75) Inventors: Liping Guo, Tianjin (CN); Qingchun He, Tianjin (CN); Zhaojun Tian, Tianjin (CN); Jie Yang, Tianjin (CN)

(73) Assignee: FREESCALE SEMICONDUCTOR, INC, Austin, TX (US)

(21) Appl. No.: 13/018,438

(22) Filed: Feb. 1, 2011

(30) Foreign Application Priority Data
Mar. 31, 2010 (CN) 201010139126.9

(51) Int. Cl. H01L 23/495; H01L 21/48

(52) U.S. Cl. 257/666; 438/123; 257/E23.037; 257/E21.499

(57) ABSTRACT

A lead frame having a recessed die bond area. The lead frame has top and bottom surfaces and a first lead frame thickness defined as the distance between the top and bottom surfaces. The lead frame has a die bond area surface located within a reduced die bond area. A second thickness is defined as the distance between the die bond area surface and the bottom surface. The second lead frame thickness is less than the first lead frame thickness such that a semiconductor die disposed and attached to the die bond area surface has a reduced overall package thickness. A side wall formed between the die bond area surface and the top surface contains the adhesive material used to attach the die, which reduces adhesive bleeding and prevents wire bonding contamination.

### BACKGROUND OF THE INVENTION

The present invention relates generally to semiconductor devices and more particularly to lead frame and semiconductor integrated circuit die assemblies within packaged semiconductor devices.

In conventional packaged semiconductor devices, such as shown in FIGS. 1A-1C, a packaged semiconductor device 40 typically includes a lead frame 10 and a semiconductor integrated circuit (IC) die 12. The lead frame 10 comprises a die bond area (also known as a die pad or flag) 14 and a plurality of conductive regions 16 (also known as lead fingers) that surround the die bond area 14. The lead frame 12 is the central supporting structure of the device 10. The die 12 typically is attached to the die bond area with an adhesive 18 such as an epoxy material. After the die 12 is attached to the lead frame 12, wires 20 are connected between die pads (not shown) of the die 12 and the conductive regions 16 of the lead frame 10 to enable electrical interconnection between the die 12 and an underlying substrate such as a printed circuit board (PCB). A mold compound 22 of ceramic or plastic material encapsulates at least a portion of the lead frame 10, the die 12 and the wires 20 to protect the die 14 and the wires 20 from the environment.

The semiconductor industry is demanding ever smaller and thinner semiconductor packages. Additionally, the number of wires and pads (sometimes referred to as pins) on semiconductor packages is increasing. These two factors have been the source of problems. One problem is that dies that are too thick may no longer be suitable because the overall thickness of the resulting package may exceed specification requirements. Another problem is adhesive or epoxy bleeding is becoming a bigger concern as the number of wires and pads increases and pad pitch decreases. Epoxy bleeding may occur when epoxy resin is used to attach IC dies to substrates or lead frames having metallic surfaces. The epoxy bleeding contaminates the wire bonds, resulting in low wire peel strength or non-stick on lead problems, which can cause device failures.

There is a need to address or at least alleviate the above problems associated with conventional packaged semiconductor devices in order to meet industry demands.

### BRIEF DESCRIPTION OF THE DRAWINGS

In order that embodiments of the invention may be fully and more clearly understood by way of non-limitative examples, the following description is taken in conjunction with the accompanying drawings in which like reference numerals designate similar or corresponding elements, regions and portions, and in which:

FIG. 1A is a top plan view of a conventional lead frame;

FIG. 1B is a cross-sectional side view of the lead frame of FIG. 1A with a die attached thereto;

FIG. 1C is a cross-sectional side view of a conventional packaged semiconductor device including the lead frame of FIG. 1A and the lead frame and die of FIG. 1B;

FIG. 2A is a top plan view of a lead frame in accordance with an embodiment of the present invention;

FIG. 2B is a cross-sectional side view of the lead frame of FIG. 2A with a die attached thereto;

FIG. 2C is a cross-sectional side view of a packaged semiconductor device in accordance with an embodiment of the present invention including the lead frame of FIG. 2A and the lead frame and die of FIG. 2B;

FIG. 2D is a cross-sectional side view of a packaged semiconductor device in accordance with another embodiment of the present invention; and

FIG. 3 is a flow chart illustrating a method of packaging an IC die in accordance with an embodiment of the invention.

### DETAILED DESCRIPTION OF THE INVENTION

An aspect of the present invention is a lead frame for receiving and being electrically connected to a semiconductor die. The lead frame includes a top surface and a bottom surface. A first lead frame thickness is defined as the distance between the top surface and the bottom surface. A reduced die bond area is disposed in the top surface for receiving a semiconductor die. The reduced die bond area has a die bond area surface between the top surface and the bottom surface and a side wall extending around a perimeter of the reduced die pad area surface to the top surface. The reduced die bond area surface and the bottom surface define a second lead frame thickness. In one embodiment of the invention, the second lead frame thickness is less than the first lead frame thickness. The lead frame also includes a plurality of conductive regions (lead fingers) arranged around and spaced apart from the perimeter of the reduced die bond area.

In other embodiments, the second lead frame thickness may be half, more than half or less than half the first lead frame thickness. The reduced die bond area surface and side wall may be sized and shaped to receive adhesive material to attach a semiconductor die to the reduced die bond area surface within the reduced die bond area and also to contain the adhesive material. This acts to prevent bleeding of the adhesive material in order to prevent the adhesive material from contaminating the top surface of the conductive regions. The top surface and the die bond area surface may be arranged to be parallel to each other, and the side wall may be perpendicular to the top surface and the die bond area surface. The side wall may have other configurations, such as straight, sloped and the like between the top surface and the die bond area surface.

In another embodiment, the present invention provides a semiconductor die package comprising a lead frame having a top surface and a bottom surface. A first lead frame thickness is defined as the distance between the top surface and the bottom surface. The lead frame has a reduced die bond area in the top surface. The reduced die bond area has a die bond area surface located between the top surface and the bottom surface and a side wall extending around a perimeter of the reduced die bond area surface to the top surface. The die bond area surface and the bottom surface define a second lead frame thickness that is less than the first lead frame thickness. The lead frame has a plurality of conductive regions (lead fingers) arranged around and spaced apart from the perimeter of the reduced die bond area. A semiconductor die has a first surface that is attached within the reduced die bond area. A second surface of the semiconductor die includes die pads that are electrically interconnected with at least one of the plurality of conductive regions (lead fingers). A package body is formed by at least partially encapsulating the semiconductor die and the lead frame with a mold compound.

In another embodiment, the present invention provides a method of a forming a lead frame for a semiconductor die package, including providing a lead frame having a top surface and a bottom surface and a first lead frame thickness defined as the distance between the top surface and the bottom surface; forming a reduced die bond area in the top surface for receiving a semiconductor die, the reduced die bond area having a die bond area surface and a side wall extending around a perimeter of the reduced die bond area surface to the top surface, and having a second lead frame thickness defined as the distance between the reduced die pad area surface and the bottom surface. The second lead frame thickness is less than the first lead frame thickness. The lead frame also has a plurality of conductive regions arranged around and spaced apart from the perimeter of the reduced die bond area.

In one embodiment, the method further comprises attaching a semiconductor die having a first surface with an adhesive layer, the first surface disposed within the reduced die bond area, and the adhesive layer disposed between the first surface of the semiconductor die and the die bond area surface for forming a lead frame die assembly. The method may further comprise interconnecting the semiconductor die with the conductive regions of the lead frame, and encapsulating the interconnected lead frame die assembly with an encapsulation material for forming a semiconductor packaged device. Before attaching the semiconductor die to the reduced die bond area, the thickness of the semiconductor die may be reduced to a desired thickness by back grinding, etching, or a combination of back grinding and etching.

Referring now to FIGS. 2A to 2C, a lead frame 50 in accordance with an embodiment of the invention is shown. FIG. 2A shows a top plan view of a lead frame 50 with a die 52 located within a reduced die bond area 54 of the lead frame 50. The lead frame 50 includes a plurality of conductive regions or lead fingers 56 that are spaced from and surround the reduced die bond area 54.

FIG. 2B shows a side cross-sectional view of a lead frame die assembly 60, where the die 52 is attached to the reduced die area 54 with an adhesive 62 and die pads (not shown) on a top or upper surface of the die 52 are electrically coupled to the conductive regions 56 with wires 64. The adhesive 62 may be an epoxy material as is known in the art. The wires 64 may be attached to the conductive regions 56 and die bonding pads of the die 52 using conventional wire bonding processes.

The lead frame 50 has a top surface 57, which is the top surface of the conductive regions 56, and a bottom surface 58, which is indicated at the bottom surface of the conductive regions 56. A first thickness of the lead frame 50 is defined as the distance between the top and bottom surfaces 57, 58. As can be seen, the die bond area 54 of the lead frame 50 has been reduced. More particularly, a thickness of the die bond area 54 is less than the above-defined first thickness. The reduced die bond area 54 includes a die bond area surface 59 located between the top surface 57 and the bottom surface 58. A side wall 61 that extends around a perimeter of the die bond area surface 59 and to the top surface 57 is formed by the reduction in thickness of the lead frame 50 at the die bond area 54. According to the present invention, a distance between the die bond area surface 59 and the bottom surface 58 defines a second lead frame thickness that is less than the first lead frame thickness. In one embodiment of the invention, the second lead frame thickness is half the first lead frame thickness, and in another embodiment of the invention, the second lead frame thickness is less than half the first lead frame thickness. In yet another embodiment, the second lead frame thickness is more than half the first lead frame thickness.

The die bond area surface 59 and the side wall 61 are dimensioned to maintain the adhesive material 62 used to attach the die 52 to the die bond area surface 59 within the reduced die bond area 54 to prevent bleeding of the adhesive material so that the adhesive material does not contaminate the top surface 57 of the lead frame 50 and the plurality of conductive regions 56. In one embodiment of the invention, the top surface 57 and the die bond area surface 59 lie in parallel planes and the side wall 61 is perpendicular to the top surface 57 and the die bond area surface 59. In another embodiment of the invention, the side wall 61 is sloped between the top surface 57 and the die bond area surface 59.

FIG. 2C is a side cross-sectional view of a packaged device 66 where a mold compound 68 of ceramic or plastic material forms the semiconductor die package body and encapsulates or partially encapsulates the lead frame die assembly 60. The mold compound 68 protects the die 52 and the wires 64 from the environment.

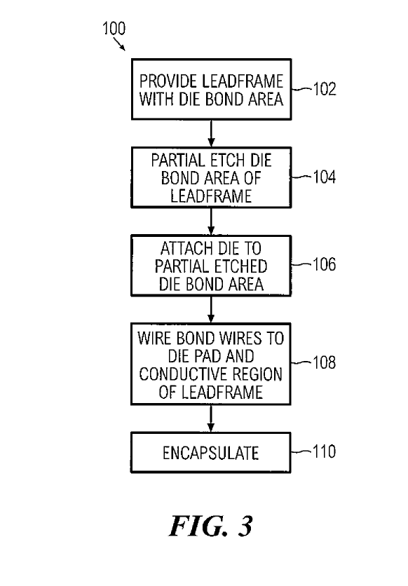

A process 100 for fabricating the packaged semiconductor device 56 in accordance with an embodiment of the invention is shown in FIG. 3. At step 102 a lead frame having a die bond area is provided. At step 104, a thickness of the die bond area is reduced by removing a portion of die bond area. For example, a typical lead frame is formed from a sheet of copper (Cu) that may be coated or alloyed with metal layers such as gold (Au), nickel (Ni), palladium (Pd) or the like. In a removal process, a marked out region of the die bond area is etched (e.g., chemical wet etching) such as by selectively applying and removing a resist material to die bond area until a predetermined amount of the die bond area has been removed (i.e., to a predetermined depth). The die bond area is not etched entirely or completely through. The bottom surface of the lead frame remains undisturbed. Thus, a reduced or recessed die bond area is formed in the top surface of the lead frame. The depth of the resulting recess may vary for specific applications and depending on the initial thickness of the lead frame prior to etching. There is no set minimum resulting thickness of the lead frame in the area of the recessed die bond area, however, the resulting thickness of the lead frame in the area of the recessed die bond area must be of sufficient thickness to provide sufficient strength or rigidity to provide adequate support during the remaining processing steps of die attach, wire bonding, encapsulation, and singulation. It should be understood that different techniques may be used to remove the material of the lead frame to form the desired recessed die bond area. For example a photolithographic based etch process may be used, or other techniques, chemistries and/or processes used to etch, grind or otherwise form the recessed die pad area and can be widely varied in accordance with embodiments of the invention.

After partially etching the die bond area, a die is attached to the die bond area with an adhesive material (e.g., tape, epoxy, solder, etc.) and then the die is electrically connected to the lead frame with a wire bonding process at step 108. The semiconductor die may be any suitable semiconductor die including an integrated circuit and die bonding pads. The assembly is then encapsulated at step 110 with an encapsulating material such as an epoxy or other plastic or ceramic material to form a semiconductor packaged device. By partial etching the die bond area, the area to which the die is attached and the surrounding area around the perimeter of the die is recessed with respect to the conductive regions. A side wall is formed by the reduction of the die bond area such that the die is surrounded by the side wall. The side wall acts to contain the adhesive used to attach the die to the die bond area, and prevent the adhesive material bleeding or otherwise contaminating the conductive regions of the lead frame. The side wall may take different shapes. For example the top surface of the lead frame and the die bond area surface may be parallel, and the side wall may be perpendicular or form a 90° angle with both the top surface of the lead frame and the die bond area surface. The side wall 69 may form different angles with the top surface and the die bond area surface, and may be straight, curved or have other configurations. As the die is recessed in the lead frame, the overall completed packaged semiconductor device is thinner or has a lower profile than device packaged with a conventional lead frame.

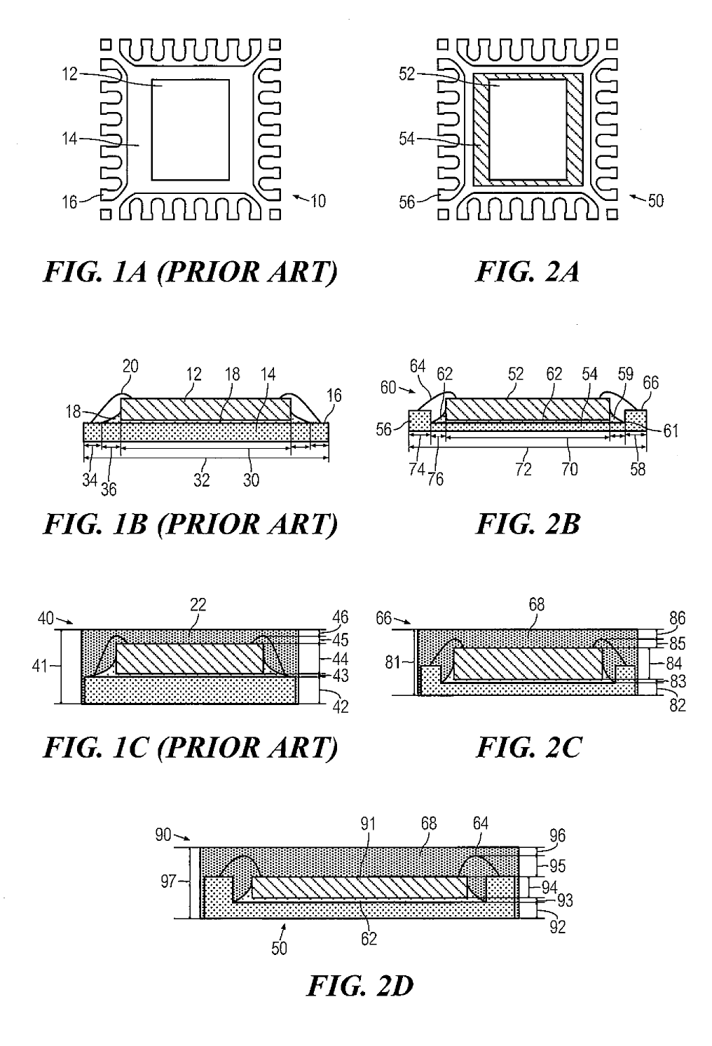

Referring now to FIGS. 1B-1C and 2B-2C, comparison of the conventional packaged device 40 with the packaged device 66 of the present invention to explain the differences and advantages of embodiments of the invention.

First, a comparison of various width measurements will be made with reference to FIGS. 1B and 2B. In FIG. 1B, the following width measurements are indicated, die width 30, overall lead frame width 32, conductive regions or lead finger width 34, and an epoxy bleed area width 36, where width 36 is essentially the width of the die bond area less the die width 30. The width of the epoxy bleed area 36 is approximate as it is possible that the epoxy bleeding may extend beyond the area 36. Some example dimensions are die width 30 can be approximately 1.94 mm, lead frame width 32 can be 3.0 mm, lead finger width 34 can be 0.15 mm, and an epoxy bleed area 36 can be 0.38 mm. (So for a lead frame with a width 32 of 3.0 mm, a lead finger width of 0.15 mm, and an epoxy bleed area width 36 of 1.94 mm, the maximum die size is 1.94 mm, but of course, smaller die may be attached to such a lead frame too).

In FIG. 2B, the following width measurements are indicated, die width 70, overall lead frame width 72, conductive regions or lead finger width 74, and an epoxy bleed area width 76. Using some of the example dimensions from above, a maximum die width can be determined. If over all lead frame width 72 remains at 3.0 mm and conductive area width 74 remains at 0.15 mm, the resin bleed area width 36 need only be about 0.1 mm wide, which would allow for a maximum die size of 2.5 mm (as compared to 1.94 mm using the conventional lead frame 10. The epoxy bleed area may be smaller than that required in conventional designs because the side wall 61 prevents epoxy bleeding.

The present invention also allows for a packaged device having a thinner profile than devices assembled using the conventional lead frame 10. A comparison will now be made using FIGS. 1C and 2C.

Referring to FIG. 1C, the conventional packaged semiconductor device 40 has a total package thickness indicated at 41. The over package thickness 41 includes lead frame thickness 42, adhesive material thickness 43, die thickness 44, wire loop height 45, and epoxy or encapsulation material thickness 46. Assigning some sample values to these dimensions, we have lead frame thickness 49 of 8 mils (0.2032 mm), adhesive material thickness 43 at 1 mil (0.254 mm), die thickness 44 at 14 mils (0.3556 mm), wire loop height 45 at 8 mils (0.2032 mm), and epoxy or encapsulation material thickness 46 at 4 mils (0.1016 mm), which adds up to 35 mils (0.889 mm).

Now referring to FIG. 2C, the packaged semiconductor device 66 in accordance with an embodiment of the present invention has a total package thickness indicated at 81. The over package thickness 81 includes reduced lead frame thickness 82, adhesive material thickness 83, die thickness 84, wire loop height 85, and epoxy or encapsulation material thickness 86. Assigning similar values as above, we have reduced lead frame thickness 82 of 3 mils (0.0762 mm), adhesive material thickness 83 at 1 mil (0.254 mm), die thickness 84 at 14 mils (0.3556 mm), wire loop height 85 at 8 mils (0.2032 mm), and epoxy or encapsulation material thickness 86 at 4 mils (0.1016 mm), which adds up to 30 mils (0.762 mm). Thus, as shown in FIG. 2C, the overall total package thickness 81 is less than the overall package thickness of the conventional device 40.

More particularly, as the recessed area depth of the recessed die bond area is approximately 5 mils (0.127 mm), the die 52 sits approximately 5 mils (0.127 mm) lower than the top surface of the portion of the lead frame that has not been etched. The bottom surface of the lead frame remains undisturbed during processing of the recessed bond area. Accordingly, the overall total package thickness of the packaged device 80 in accordance with an embodiment of the invention is approximately 5 mils (0.127 mm) less than the conventional packaged semiconductor 40 shown in FIG. 1C.

Referring now to FIG. 2D, another embodiment of a lead frame and packaged semiconductor device in accordance with the present invention is shown. In FIG. 2D, a side cross-sectional view of a packaged semiconductor device 90 is shown. The device 90 includes the lead frame 50, adhesive material 62, wires 64 and encapsulant 68 of the first embodiment described above. A die 91 is attached to the lead frame 50, and in this embodiment, the die 91 undergoes an additional step of back grinding to reduce the thickness of the die 91 prior to attachment to the lead frame 50. With back grinding, the thickness of the die 91 can be reduced from 14 mils (0.3556 mm) to about 5 mils (0.1270 mm). As the die thickness is reduced, the overall thickness of the packaged semiconductor 90 is reduced.

For comparison with the packaged semiconductor 80 of FIG. 2C, corresponding dimensions are used. Thus, we have reduced lead frame thickness 92 of 3 mils (0.0762 mm), adhesive material thickness 93 at 1 mil (0.254 mm), die thickness 94 at 5 mils (0.1270 mm), wire loop height 95 at 8 mils (0.2032 mm), and epoxy or encapsulation material thickness 96 at 4 mils (0.1016 mm), which adds up to 21 mils (0.5334 mm). Thus, as shown in FIG. 2D, the overall total package thickness 97 is less than the overall package thickness 81 of the first embodiment and much less than the over package thickness of the conventional device 40.

A back surface grinder may be used to back grind a surface of the die such as the back or bottom surface of the semiconductor die to reduce the thickness of the die to a desired thickness, for example 3 mil (0.0762 mm) or (4 mil (0.1016 mm) from 14 mil (0.3556 mm) or the like. The process of reducing the thickness of the die may be replaced by other means other than back grinding, such as for example, etching, a combination of back grinding and etching, or the like. The die thickness may be reduced to suit specific design requirements, however, other factors such as die warpage are considered to determine the minimum thickness of the die.

While embodiments of the invention have been described and illustrated, it will be understood by those skilled in the technology concerned that many variations or modifications in details of design or construction may be made without departing from the present invention.

1. A lead frame for receiving and being electrically connected to a semiconductor die, the lead frame comprising:
a top surface and a bottom surface, wherein a first lead frame thickness is defined as the distance between the top and bottom surfaces;
a reduced die bond area in the top surface for receiving a semiconductor die, the reduced die bond area having a die bond area surface located between the top surface and the bottom surface and a side wall extending around a perimeter of the die bond area surface to the top surface, wherein a distance between the die bond area surface and the bottom surface defines a second lead frame thickness that is less than the first lead frame thickness; and
a plurality of conductive regions arranged around and spaced apart from the die bond area surface.

2. The lead frame of claim 1, wherein the second lead frame thickness is half the first lead frame thickness.

3. The lead frame of claim 1, wherein the second lead frame thickness is less than half the first lead frame thickness.

4. The lead frame of claim 1, wherein the die bond area surface and the side wall are dimensioned to receive adhesive material used to attach a semiconductor die to the die bond area surface within the reduced die bond area and containing the adhesive material within the reduced die bond area to prevent bleeding of the adhesive material so that the adhesive material does not contaminate the top surface of the lead frame and the plurality of conductive regions.

5. The lead frame of claim 1, wherein the top surface and the die bond area surface are lie on parallel planes.

6. The lead frame of claim 1, wherein the side wall is perpendicular to the top surface and the die bond area surface.

7. The lead frame of claim 1, wherein the side wall is sloped between the top surface and the die bond area surface.

8. A semiconductor die package comprising:
a lead frame having a top surface and a bottom surface, wherein a first lead frame thickness is defined as the distance between the top surface and the bottom surface, the lead frame having a reduced die bond area in the top surface, the reduced die bond area having a die bond area surface located between the top surface and the bottom surface and a side wall extending around a perimeter of the die bond area surface to the top surface, the die bond area surface and the bottom surface defining a second lead frame thickness that is less than the first lead frame thickness, the lead frame having a plurality of conductive regions arranged around and spaced apart from a perimeter of the die bond area surface;
a semiconductor die having a first surface and a second surface, the first surface attached to the die bond area surface within the reduced die bond area, and the second surface having a plurality of die bond pads for electrical interconnection with at least one of the plurality of conductive regions; and
an encapsulation material that at least partially encapsulates the semiconductor die and the lead frame.

9. The semiconductor die package of claim 8, further comprising wires electrically connecting the die bond pads and the conductive regions.

10. The semiconductor die package of claim 8, wherein the wires are wire bonded to the die bond pads and the conductive regions.

11. The semiconductor die package claim 8, wherein the second lead frame thickness is half the first lead frame thickness.

12. The semiconductor die package of claim 8, wherein the second lead frame thickness is less than half the first lead frame thickness.

13. The semiconductor die package of claim 8, wherein the die bond area surface and the side wall are dimensioned to receive an adhesive material, the adhesive material for attaching the semiconductor die to the die bond area surface and contain the adhesive material so that the adhesive material does not bleed onto the plurality of conductive regions.

14. The semiconductor die package of claim 8, wherein the top surface and the die bond area surface are parallel.

15. The semiconductor die package of claim 8, wherein the side wall is perpendicular to the top surface and the die bond area surface.

16. A method of a packaging a semiconductor die, comprising the steps of:
providing a lead frame having a top surface and a bottom surface, wherein a first lead frame thickness is defined as a distance between the top surface and the bottom surface, the lead frame including a reduced die bond area in the top surface for receiving a semiconductor die, the reduced die bond area having a die bond area surface and a side wall extending around a perimeter of the die bond area surface to the top surface, wherein a second lead frame thickness that is less than the first lead frame thickness is defined as a distance between the die bond area surface and the bottom surface, and the lead frame further including a plurality of conductive regions arranged around and spaced apart from the perimeter of the reduced die bond area.

17. The method of packaging a semiconductor die of claim 16, further comprising attaching a first surface of a semiconductor die to the die bond area surface with an adhesive.

18. The method of packaging a semiconductor die of claim 17, further comprising:
electrically connecting the semiconductor die with the conductive regions of the lead frame; and
encapsulating the lead frame and the semiconductor die with an encapsulation material.

19. The method of packaging a semiconductor die of claim 17, further comprising reducing the thickness of the semiconductor die before attaching the semiconductor die to the die bond area surface.

20. The method of claim 19, wherein the reducing the thickness of the semiconductor die is by back grinding.
